(19) United States
(12) Patent Application Publication
(10) Pub. No.: US 2023/0384625 A1
(43) Pub. Date: Nov. 30, 2023

(54) Creation of Single Photons

(71) Applicants: Fraunhofer-Gesellschaft zur Förderung der angewandten Forschung e.V., München (DE); Friedrich-Schiller-Universität Jena, Jena (DE)

(72) Inventors: Falk Eilenberger, Jena (DE); Tobias Vogl, Jena (DE)

(73) Assignees: Fraunhofer-Gesellschaft zur Förderung der angewandten Forschung e.V., München (DE); Friedrich-Schiller-Universität Jena, Jena (DE)

(21) Appl. No.: 18/032,013

(22) PCT Filed: Oct. 14, 2021
(86) PCT No.: PCT/EP2021/078471

§ 371 Date: Apr. 14, 2023

(30) Foreign Application Priority Data
Oct. 14, 2020 (DE) 102020126956.0

(51) Int. Cl. G02F 1/015; H01S 5/14; H01S 5/04

(52) U.S. Cl. CPC G02F 1/0154; H01S 5/141; H01S 5/041; G02F 2203/15

(57) ABSTRACT

A method is proposed for generating single photons with a predetermined wavelength f_{V}, with the following steps:
i) generating a single photon, preferably in a source and a resonator, wherein the single photon has a resonator wavelength f_{R} and a resonator bandwidth f_{BR},
ii) measuring the resonator wavelength f_{R}, preferably in a wavelength standard, wherein the single photon is guided from the resonator to the wavelength standard via a beam guide,
iii) comparing the resonator wavelength f_{R} with the predetermined wavelength f_{V} and generating a control signal on the basis of the comparison, preferably in a controller,
iv) adjusting the resonator using the control signal in order to change the resonator wavelength f_{R} toward or to the predetermined wavelength f_{V},
v) repeating steps i to iv) until the resonator wavelength f_{R} corresponds to the predetermined wavelength f_{V} and then coupling out.

### CROSS-REFERENCE TO RELATED APPLICATIONS

The present application is a national phase entry under 35 U.S.C. § 371 of International Application No. PCT/EP2021/078471, filed on Oct. 14, 2021, published as WO 2022/079180 A1, which claims priority from German Patent Application No. 10-2020-126-956.0, filed on Oct. 14, 2020, all of which are hereby incorporated herein by reference in their entireties.

### TECHNICAL FIELD

The invention relates to a method for generating single photons according to the features of the preamble of claim 1 and a device for generating single photons according to the features of the preamble of claim 14.

Methods and devices for generating single photons are already known. Single photons can be generated for example by spontaneous emission in isolated ions and atoms or spontaneous conversion in nonlinear materials or in quantum dots. The known methods and devices have the disadvantage that the properties of the single photons generated are defined by the source. Since sources are very sensitive to external influences such as ageing, radiation effects, temperature fluctuations or mechanical actions, the properties of the single photons generated change over the course of time. A long-term stability, for example with respect to the wavelengths of the single photons, cannot be guaranteed in such systems. Single photons are of great importance in particular for quantum cryptography, quantum information or optical communication, wherein the indistinguishability of the single photons generated is essential here. Further, single photons can also be used for quantum memories, wherein the disadvantage of known sources for single photons is that the single photons generated do not operate precisely on the wavelength of the quantum memory and thus only a low efficiency can be achieved in the coupling of the single photon to the quantum memory.

The object of the present invention is to provide a method that is improved, more precise, more cost-effective, and more stable over a long period, and such a device for generating single photons.

The object is achieved according to the invention by a method for generating single photons according to the features of claim 1.

According to the invention, a method is proposed for generating single photons with a predetermined wavelength f_{V}, preferably for use for optical communication, quantum cryptography and/or quantum information, wherein the method comprises the following steps:
i) generating a single photon, preferably in a source and a resonator, wherein the single photon has a resonator wavelength f_{R} and a resonator bandwidth f_{BR},
ii) measuring the resonator wavelength f_{R}, preferably in a wavelength standard, wherein the single photon is guided from the resonator to the wavelength standard via a beam guide. The following steps are important here
iii) comparing the resonator wavelength f_{R} with the predetermined wavelength f_{V} and generating a control signal on the basis of the comparison, preferably in a controller,
iv) adjusting the resonator using the control signal in order to change the resonator wavelength f_{R} toward or to the predetermined wavelength f_{V},
v) repeating steps i to iv) until the resonator wavelength f_{R} corresponds to the predetermined wavelength f_{V} and then coupling out a single photon with the predetermined wavelength f_{V} into an output, preferably through the beam guide.

Further, the object is achieved by a device for generating single photons with a predetermined wavelength f_{V} according to the features of claim 14.

According to the invention, a device is proposed for generating single photons with a predetermined wavelength f_{V}, preferably for use for optical communication, quantum cryptography and/or quantum information, wherein the device has a source, a resonator, a beam guide and a wavelength standard, and wherein the source and the resonator generate single photons with a resonator wavelength f_{R} and a resonator bandwidth f_{BR}, and wherein the beam guide guides the single photon from the resonator to the wavelength standard or to an output, and wherein the wavelength standard measures the wavelength of the single photon. It is important here that the device has a controller and that the device has a control circuit for regulating the resonator wavelength f_{R} to the predetermined wavelength f_{V}, wherein the control circuit is formed of the resonator as actuating means, the wavelength standard as measuring device and the controller for controlling the resonator.

The advantage of the method according to the invention and of the device according to the invention is that single photons with exactly the desired predetermined wavelength f_{V} can be generated over a long period through the combination of the source with the resonator and the regulation by the control circuit. Through the regulation, environmental fluctuations such as for example temperature fluctuations or radiation effects for example in space and also change in the material or material fatigue of the components can be compensated for. The quality of the source with respect to efficiency and stability can likewise be improved. The method according to the invention and the device according to the invention guarantee a robust and constantly high-quality generation of single photons with the desired predetermined wavelength f_{V}.

A constant wavelength during the generation of single photons is of great importance among other things for optical communication and quantum cryptography, since in the case of such applications the indistinguishability of the single photons is important and, for example, maintenance cannot be carried out on single-photon sources on satellites. A precise adjustability of the wavelength of the single photons to the desired predetermined wavelength f_{V} is highly advantageous since, for example in the case of the application in optical communication and quantum cryptography or in quantum key distribution (QKD), the predetermined wavelength f_{V} is chosen such that a particularly high contrast with respect to daylight is achieved. This makes optical communication with single photons possible even in daylight.

For example in the method of quantum key distribution, also called QKD, which represents a branch of quantum cryptography, a more secure key between two parties is generated by the exchange of single photons. This key can be used to then encrypt a message and then decrypt it again, for example using the one-time pad method (one-time encryption). In contrast to conventional encryption methods, the security of the generation of the key in quantum key distribution is based on quantum mechanical effects, which detect an unauthorized measurement or manipulation. The key generated can thereby be classified as secure, or be classified as insecure if a manipulation is detected.

The precise adjustability of the wavelength of the single photons to the desired predetermined wavelength f_{V} is further highly advantageous in quantum memories. Quantum memories can act as a component for a quantum repeater in quantum networks, as a qubit buffer (synchronization of several photon qubits or single-photon sources) or as a type of quantum RAM in quantum computers. The frequently used approaches for a quantum memory include warm/cold alkali gases or doped solid-state crystals. The storage is effected here in a particular transition between two states. However, this restricts the wavelength for coupling to this transition. With the method according to the invention and the device according to the invention, the wavelengths can be adjusted exactly to the required wavelength, whereby the coupling of the single photons generated according to the invention to the quantum memory is effected with a very high efficiency.

It can be provided that steps i) to iv) or step v) form a regulation in the case of or during the generation of single photons with the predetermined wavelength f_{V}.

It can be provided that the wavelength of the single photon, preferably in step i), corresponds to a control variable, and/or
that the measured resonator wavelength f_{R}, preferably in step ii), corresponds to an actual value, and/or
that the predetermined wavelength f_{V} corresponds to a set point.

It can be provided that in step iii) the controller compares the actual value and the set point and that the controller calculates and/or generates the control signal on the basis of the comparison.

It can be provided that the regulation comprises
a) measuring the resonator wavelength f_{R}, preferably in the wavelength standard as measuring device, preferably in step ii),
b) comparing the wavelengths and generating the control signal, preferably in the controller, preferably in step iii), and
c) adjusting the resonator using the control signal, preferably with the resonator as actuating means, preferably in step iv).

Actuating means denotes in particular the part of the control circuit which contains the physical variable to be regulated, on which the controller is to act via the control signal. The control signal can for example be an electrical signal, the size of which is proportional to the measured deviation from the predetermined wavelength f_{V}. It is also possible for the control signal to be an electrical signal, which indicates the direction in which the change is effected in order to reach the predetermined wavelength f_{V}. The physical variable can, depending on the resonator, be for example the distance between the mirrors in order to act on the resonator wavelength f_{R}. The physical variable can preferably be the refractive index and/or the composition of a material between the mirrors. The actuating means can preferably be acted on chemically and/or thermally and/or electrically and/or mechanically and/or optically in order to adjust the resonator wavelength f_{R}.

The regulation is preferably carried out until it is true for the single photons generated in step i) that the resonator wavelength f_{R} corresponds to the predetermined wavelength f_{V} or lies within a predetermined deviation from the predetermined wavelength, or the amount of the difference between the measured resonator wavelength f_{R} and the predetermined wavelength f_{V} lies below a predefined limit value.

It can be provided that the controller in the device and/or in step iii) is formed as a continuous controller. The controller can preferably be formed as a proportional controller (P controller) or as a proportional integral controller (PI controller) or as a proportional derivative controller (PD controller) or as a proportional integral derivative controller (PID controller).

It can be provided that in step iii) a proportional or a proportional integral or a proportional derivative or a proportional integral derivative control signal is generated in the controller, preferably is generated in dependence on the comparison of the resonator wavelength f_{R} with the predetermined wavelength f_{V}.

It can be provided that the controller in the device and/or in step iii) is formed as a discontinuous controller. The controller can be formed for example as a two-point controller.

It can be provided that the controller in the device and/or in step iii) is formed as a discrete, in particular a time-discrete, controller.

It can be provided that the controller, preferably in step iii), is formed as a digital controller or as an analog circuit.

It can be provided that steps i) to iv) are repeated until the resonator wavelength f_{R} of the single photon generated in step i) lies in a range of ±0.2 nm, preferably ±0.01 nm, most preferably ±0.001 nm, around the predetermined wavelength f_{V}. It can be provided that the range of ±0.2 nm, preferably ±0.01 nm, most preferably ±0.001 nm, around the predetermined wavelength f_{V} represents a control threshold.

Once the resonator has been set to the predetermined wavelength f_{V}, the control circuit can be deactivated at least temporarily or periodically, in order to use the photons generated for optical communication and/or quantum cryptography and/or quantum information. While the control circuit is deactivated, the source or the resonator generates photons with the predetermined wavelength G. However, it can happen that the wavelength of the resonator changes because of external influences and/or over time. In order to check the wavelength of the photons generated, the control circuit can be periodically switched on again for a particular time, in particular in order to set the resonator to the predetermined wavelength f_{V} again.

It can be provided that the control circuit is permanently active, wherein, for this, the resonator preferably couples out single photons in a first direction toward the wavelength standard and uses them for the regulation, and couples out single photons in a second direction toward the output. It can be provided that the resonator walls are formed as semi-transparent mirrors, wherein the transmissivity determines the probability of coupling out a single photon in the first and/or second direction. The probability of coupling out toward the wavelength standard is preferably smaller than the probability of coupling out toward the output.

It can be provided that the control circuit is permanently active, wherein, for this, the resonator functions as a beam splitter and separates between one and/or more modes for coupling out and one and/or more modes for the control circuit.

It can be provided that the regulation is repeated after the first generation of a single photon with a predetermined wavelength f_{V} with a frequency of from 1 to 10 Hz, preferably 10 to 1 kHz, most preferably 1 kHz to 100 kHz. For the regulation, a single photon can be used in order to determine a control signal. If the resonator wavelength f_{R} deviates from the predetermined wavelength f_{V} by more than a predetermined control threshold, several successive photons can be used for the regulation, in particular until the resonator wavelength f_{R} corresponds to the predetermined wavelength f_{V}, or lies within a predetermined deviation from the predetermined wavelength, or the amount of the difference between the measured resonator wavelength f_{R} and the predetermined wavelength f_{V} lies below a predefined limit value, wherein disturbances such as dark counts for example are preferably taken into consideration.

In addition, it can be provided that the regulation is effected depending on the frequency of the generation of the single photons in a predetermined duty cycle. In particular, a particular duty cycle can be predefined, in particular in the range of from 1:10 to 1:10000, preferably to 1:100000. For example, only every tenth single photon or only every fiftieth single photon or only every hundredth single photon or only every thousandth single photon can be used for a determination of the control signal.

The repetition of the regulation can preferably be matched to the external influences or to the measured deviations from the predetermined wavelength f_{V}, preferably by measuring parameters such as temperature, humidity, radiation effects, pressure, vibration and time for example and supplying them to the control circuit as measured variables, in particular in order to adjust the frequency or the duty cycle of the regulation. In particular, the repetition of the regulation can be adjusted such that the frequency of the regulation is increased in the case of expected or measured sharp changes in the resonator wavelength f_{R}.

It can be provided that the predetermined wavelength f_{V} is one of the Fraunhofer lines. Fraunhofer lines are absorption lines in the spectrum of the Sun which form due to the transmission of the sunlight through the atmosphere of the Sun. Through the predetermined wavelength f_{V} as Fraunhofer lines, a reduction of the error rate in quantum cryptography or optical communication due to foreign photons is achieved, whereby a high data rate is made possible even in daylight or under a full moon.

The predetermined wavelength f_{V} is preferably one of the Fraunhofer lines of 898.765 nm or 822.696 nm or 759.37 nm or 686.719 nm or 656.281 nm or 627.661 nm or 589.592 nm or 588.995 nm or 587.562 nm or 546.073 nm or 527.039 nm or 518.362 nm or 517.27 nm or 516.891 nm or 516.751 nm or 516.733 nm or 495.761 nm or 486.134 nm or 466.814 nm or 438.355 nm or 434.047 nm or 430.79 nm or 430.774 nm or 410.175 nm or 396.847 nm or 393.368 nm or 382.044 nm or 358.121 nm or 336.112 nm or 302.108 nm or 299.444 nm.

For applications in quantum information, quantum communication or quantum data processing, or in the case of coupling to a quantum memory, the predetermined wavelength f_{V} is preferably one of the atomic transitions of rubidium (780.027 nm or 794.760 nm) or cesium (852.113 nm or 894.347 nm) or sodium (588.995 nm or 589.592).

It can be provided that the predetermined wavelength f_{V} corresponds to a transition between two states of a quantum memory. It can be provided that this transition is a defect site in a solid-state crystal.

It can be provided that the single photon with the predetermined wavelength f_{V}, preferably in step v), has the resonator bandwidth f_{BR} of at most 0.5 nm, preferably of at most 0.1 nm, most preferably of at most 0.01 nm. It is preferably provided that the resonator bandwidth f_{BR} is limited by the maximum width of the Fraunhofer line. For example, the width of the Fraunhofer line is 0.286 nm for 434 nm, 0.075 nm for 589 nm or 0.056 nm for 589 nm or 0.4 nm for 656 nm or 0.36 nm for 854 nm. The advantage of a small bandwidth, which even lies below the bandwidth of the corresponding Fraunhofer line, makes a wavelength multiplexing possible within the Fraunhofer line for an optical communication or quantum cryptography between several participants or between two participants with higher data rates.

It can be provided that the single photon is generated in step i) by spontaneous emission or spontaneous parametric conversion, preferably that the single photon is generated in the source by excitation of a solid-state crystal or a nonlinear crystal or heterostructure or a two-dimensional structure, preferably by excitation with a pump signal.

It can be provided that the pump signal is an electrical pump signal, most preferably an electrical pump pulse signal, or preferably a pump laser beam, preferably a pulsed pump laser beam.

It can be provided that the source has an electric circuit and/or a pump laser for the pump signal and a solid-state crystal or a nonlinear crystal or a heterostructure or a two-dimensional structure.

It can be provided that the electric circuit and/or the pump laser excites the solid-state crystal or the nonlinear crystal or the heterostructure or the two-dimensional structure for the emission.

It can be provided that the lifespan of the state excited for the emission in the source, preferably in the source without the resonator, lies in the range of from 10 ns to 1 ns, preferably in the range of from 1 ns to 0.1 ns, most preferably in the range of from 0.1 ns to 0.01 ns.

It can be provided that the pulsed pump laser excites the source with a frequency in the range of from 1 MHz to 100 MHz, preferably in the range of from 100 MHz to 1 GHz, most preferably in the range of from 1 GHz to 100 GHz. The frequency is preferably only limited by the maximum lifespan of the emission. The advantage of a high frequency is the number of single photons generated, wherein the resolution of the detectors and the losses need to be taken into consideration in the case of use for quantum cryptography or optical communication.

It can be provided that in the source, preferably in step i), a single photon is generated by heralded spontaneous parametric down-conversion (hSPDC). It can be provided that the source has a pump laser, preferably a pulsed pump laser, and a nonlinear crystal. Through the pumping of the nonlinear crystal, a photon pair can be generated by spontaneous parametric down-conversion. Heralded describes the process where a photon pair is generated and the measurement of the first photon confirms (heralds) the generation of the second photon without disrupting the generation of the second photon by a measurement of the second photon.

It can be provided that in the source, preferably in step i), a single photon is generated by emission in a semiconductor quantum dot. It can be provided that the source is formed as a semiconductor quantum dot.

It can be provided that in the source, preferably in step i), a single photon is generated by emission in an ion trap. It can be provided that the source is formed as an ion trap.

It can be provided that in the source, preferably in step i), a single photon is generated by emission in a solid with defects. It can be provided that the source is formed as a solid with defects.

It can be provided that the single photons are generated in step i) by excitation of a two-dimensional hexagonal boron nitride structure with impurities with a pulsed laser.

It can be provided that the source is formed as a hexagonal boron nitride structure with impurities. The advantage of the two-dimensional hexagonal boron nitride structure with impurities is that the single photons generated adjustably have a wavelength in the range between 300 nm and 1000 nm with a bandwidth of approx. 5 nm, wherein the adjustability is provided through the choice of a particular impurity with the desired properties. An advantage of such sources is the high resistance to radiation, for example in space, and the long operational lifespan of such sources.

It can be provided that in step i)
d) the source is excited by the resonator to emit the single photon with a resonator wavelength f_{R} and a resonator bandwidth f_{BR}, wherein the source without resonator preferably has a source bandwidth f_{QR} which is larger than the resonator bandwidth f_{BR}, or
e) the source generates a single photon with a source wavelength f_{Q} and a source bandwidth f_{BQ} and the resonator filters therefrom a single photon which has the resonator wavelength f_{R} and the resonator bandwidth f_{BR}, wherein the predetermined wavelength f_{V} and the resonator wavelength f_{R} are contained in the range of the source bandwidth f_{BQ}.

It can be provided that in case d) the source is arranged in the resonator or that in case e) the source is arranged outside the resonator.

It can be provided that in case d) the source without resonator has a source bandwidth f_{QR} which is larger than the resonator bandwidth f_{BR} and only an emission of the single photon with a resonator wavelength f_{R} and a resonator bandwidth f_{BR} is possible in the source due to the arrangement in the resonator.

The advantage of an arrangement of the source in the resonator is that the probability of a spontaneous emission of the single photons in the source with the resonator wavelength f_{R} and with the resonator bandwidth f_{BR} is increased by the resonator. In the process, the linewidth of the emission falls to resonator wavelength f_{R} due to the coupling of the source to the resonator. Further, through the coupling the resonator reduces the lifespan of the excited state and thus increases the emission rate of the single photons with the resonator wavelength f_{R}. The advantage of an arrangement of the source outside the resonator is the simple arrangement and formation of the source and the resonator.

It can be provided that the source in the resonator is arranged in the focus point of the resonator.

It can be provided that in step iv) the resonator is regulated and/or formed so that it can be regulated chemically, thermally, electrically, mechanically and/or optically. Preferably, the distance between the resonator walls is changed and/or the refractive index of a material in the resonator is changed by the chemical, thermal, electrical, mechanical and/or optical regulation.

It can be provided that the control signal is an electrical signal which brings about the regulation of the resonator.

It can be provided that the resonator is adjusted and/or is formed so that it can be adjusted mechanically and/or electrically by a piezo motor or a piezo actuator or a piezoelectric signal. It can be provided that the piezo motor changes the distance between the resonator walls. It can be provided that the piezoelectric signal brings about the change in length of a material in the resonator in order to change the distances between the resonator walls.

It can be provided that the resonator is regulated and/or is formed so that it can be regulated optically and/or electrically by an electro-optic modulator. It can be provided that the electro-optic modulator changes the refractive index of a material in the resonator.

It can be provided that the resonator is regulated chemically and/or thermally by changing the refractive index of a gas or material in the resonator.

The resonator is preferably adjusted by the piezo motor as a mechanical regulation or by the piezoelectric signal as an electrical regulation.

It can be provided that the resonator is adjusted in constant steps or continuously on the basis of the size of the control signal. It can be provided that the resolution of the adjustment of the resonator wavelength f_{R} is at least 0.1 nm, preferably 0.01 nm, most preferably 0.001 nm. For multiplexing, a resonator wavelength f_{R} of 0.001 nm or less is preferred.

It can be provided that the resonator is an optical resonator, preferably the resonator is formed as an optical cavity or a cavity resonator. A single photon with the resonator bandwidth f_{BR} of 0.1 nm, preferably 0.01 nm, most preferably 0.001 nm, is preferably formed by the resonator.

The resonator bandwidth f_{BR} is preferably smaller than or equal to a target wavelength bandwidth, wherein the target wavelength bandwidth is determined by a target wavelength, thus the wavelength for optical communication, quantum cryptography and/or quantum information, i.e. for example the target wavelength is one of the Fraunhofer lines and the target wavelength bandwidth is the width of this Fraunhofer line.

The resonator bandwidth f_{BR} is preferably smaller than the target wavelength bandwidth, preferably at most half the target wavelength bandwidth, most preferably the target wavelength bandwidth corresponds to a multiple of the resonator bandwidth f_{BR}. The advantage of such a narrow-band single photon is that several systems for generating the single photons can be combined with each other, which generate single photons with different wavelengths which, however, for example all lie in a particular Fraunhofer line. It is thus possible to carry out a wavelength multiplexing within the Fraunhofer lines.

It can be provided, preferably in step i), that the resonator is coupled photonically and/or mechanically to the source. Through the photonic coupling of the resonator to the source, the wavelength and the bandwidth of the single photon are adjusted to the resonator wavelength f R and the resonator bandwidth f_{BR}. The lifespan of the spontaneous emission in the source is preferably reduced due to the photonic coupling. Through the mechanical coupling of the resonator to the source, the source is formed fixed on or in the resonator.

It can be provided that the resonator is formed of two resonator walls, preferably highly reflective resonator walls. It can be provided that, in the case of the resonator consisting of two resonator walls, the resonator walls are formed movable relative to each other in order to adjust the resonator bandwidth f_{BR} and/or that a material or gas is formed between the resonator walls in order to change the refractive index between the resonator walls in order to adjust the resonator bandwidth f_{BR}.

It can be provided that the resonator is formed as a plasmonic nanocavity, wherein the plasmonic nanocavity is preferably generated by coupling two nanostructures with a subnanometer distance between them or wherein the plasmonic nanocavity is generated by engraving nanoholes in thin metallic films. Plasmons describe coupled oscillations in the Fermi gas of metals and photons.

It can be provided that the resonator is formed of photonic crystals. A photonic crystal has periodic structures, preferably periodically etched structures. The photonic crystal is preferably formed by a structure with alternating high and low refractive index.

It can be provided that the resonator is formed as a ring resonator, wherein the ring resonator consists of a waveguide and the single photon can couple into and out of it evanescently.

It can be provided that the resonator consists of several optically active nanoparticles of semiconductors or dielectrics. It can be provided that the resonator consists of optical micro- or nano structures.

It can be provided that the resonator has one or more optical elements and/or one or more optical structures in order to influence the direction, propagation, transverse and/or longitudinal mode and/or focusing of the photons. The one or more optical elements and/or one or more optical structures are preferably formed or arranged inside the resonator and/or on the outside of the resonator in order to influence the propagation, the mode and/or the focusing both in the resonator and during the coupling of the single photon out of the resonator. The difference between optical elements and optical structures is preferably that the optical elements are arranged as additional elements in the resonator and the optical structures are formed by the resonator itself, preferably by the resonator walls and/or a material in the resonator for changing the refractive index for the regulation of the resonator.

It can be provided that the one or more optical elements and/or one or more optical structures are formed as lenses or lens systems or are formed as gratings, preferably as output optics.

It can be provided that the resonator is formed as a confocal resonator or as a resonator with a plane mirror and a concave mirror. The advantage of these designs is that a source in the resonator can be arranged in the focus of the resonator.

It can be provided that one or both resonator walls are formed transparent for the pump laser; preferably for sources in the resonator, that the pump laser is focused on the source by the one or more optical elements or one or more optical structures.

It can be provided that the resonator walls are formed of an optical multilayer system. The refractive indices preferably differ in the layers in order to achieve an antireflective effect or a mirror effect for the pump laser and/or the single photon.

It can be provided that a material is formed between the resonator walls, preferably in order to change the refractive index in the resonator and/or in order to change the distance between the resonator walls. The material preferably has a receptacle for the source in order not to touch the source. The material is preferably able to be regulated chemically, thermally, electrically, mechanically and/or optically in order to adjust the resonator. The material is preferably a polymer, most preferably a silicon-based polymer, for example polydimethylsiloxane (PDMS).

It can be provided that the resonator consists of semiconductive, dielectric and/or metallic materials.

It can be provided that the emission of the excited state is improved by a factor of 2, preferably by a factor of 10, most preferably by a factor of 100, through the coupling of the source to the resonator.

It can be provided that the measurement in step ii) is effected through a dispersive element or through an absorber, preferably through a grating and/or a prism and/or one or more spectral filters on absorptive or reflective basis and/or a chemical absorber and/or a gas or vapor or plasma, preferably in a gas cell.

It can be provided that the wavelength standard is formed as a grating and/or a prism and/or one or more spectral filters on absorptive or reflective basis and/or a chemical absorber and/or a gas or vapor or plasma, preferably in a gas cell.

It can be provided that the measurement in step ii) is effected by spectroscopy or by Fourier-transform spectroscopy, preferably in a spectroscope or a Fourier-transform spectroscope.

It can be provided that the resolution of the measurement in step ii) is at least 0.5 nm, preferably 0.01 nm, most preferably 0.001 nm. It can be provided that the resolution of the measurement in step ii) at least corresponds to the target wavelength bandwidth.

It can be provided that for the measurement, preferably in step ii), a single-photon detector is arranged after the dispersive element in order to detect single photons.

It can be provided that the single-photon detector is formed as an avalanche diode (Zener diode with avalanche effect) or avalanche photodiode.

It can be provided that the resonator wavelength f_{R} is adjusted to the predetermined wavelength f_{V} through an absorption or reflection of the single photon in the dispersive element by minimizing the detection on the single-photon detector through adjustment of the resonator.

It can be provided that the resonator wavelength f_{R} is adjusted to the predetermined wavelength f_{V} through a reflection or transmission of the single photon in the dispersive element by maximizing the detection on the single-photon detector through adjustment of the resonator.

It can be provided that the dispersive element and/or the single-photon detector is calibrated before the regulating by readjusting the resonator over a fluctuation range using the control signal and measuring the dispersive element and/or the single-photon detector.

It can be provided that the wavelength standard and the pulsed pump laser are synchronized with each other as a reference for generating the single photons, preferably using a trigger signal.

It can be provided that the beam guide is formed switchable in order to guide the single photon from the source and the resonator to the wavelength standard in step i) and ii) and to guide the single photon from the source and the resonator to an output in step v), preferably to guide the single photon with the predetermined wavelength f_{V}, most preferably to guide the single photon to the output if the previously measured single photon has exhibited the predetermined wavelength f_{V}.

It can be provided that the beam guide is formed as an active optical element, preferably as a controllable mirror, preferably as an electro-optic modulator with a polarization element, or an acousto-optic modulator or as a liquid crystal. The polarization element preferably guides single photons with a first polarization from the source and the resonator to the wavelength standard, preferably by transmission, and guides, preferably reflects, single photons with a second polarization, influenced by the electro-optic modulator, from the source and the resonator to the output. The propagation direction of the single photon in the acousto-optic modulator is preferably influenced, wherein in a first switch position the single photon is guided on a first path to the wavelength standard and in a second switch position the single photon is guided on a second path to the output.

It can be provided that the active optical element is controlled by a control device in order to switch between a measurement and the coupling-out of the single photon. The advantage of an active optical element is that the regulation can be actively adjusted at desired times and with a desired duration, for example if the single photons generated are currently not needed for an optical communication, or before the optical communication is effected.

It can be provided that the beam guide is formed as a passive optical element, preferably as a beam splitter. The advantage of a passive optical element is the simple and cost-effective embodiment and the continuous regulation of the wavelength.

It can be provided that the beam splitter is formed as a 99/1 beam splitter, i.e. that on average only every 100th single photon is guided toward the wavelength standard.

Further embodiments of the invention are represented in the figures and described in the following. In the figures, a possible design of the invention is shown by way of example. This design serves to explain a possible implementation of the invention and is not to be understood to be limitative. There are shown in:

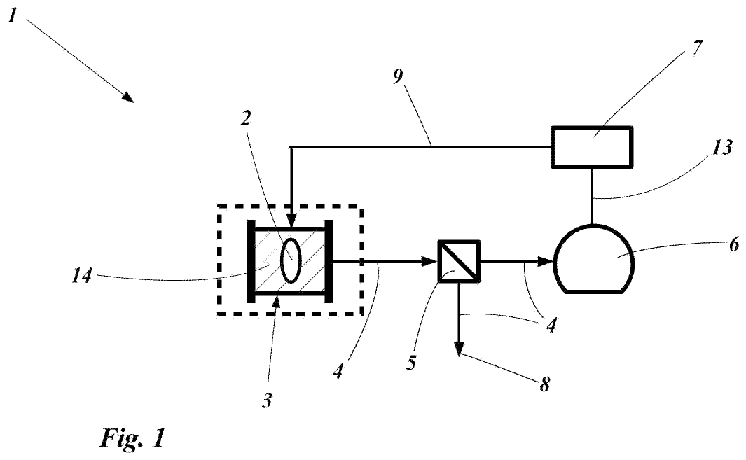

FIG. 1 is a schematic representation of the method and the device for generating single photons with a predetermined wavelength f_{V};

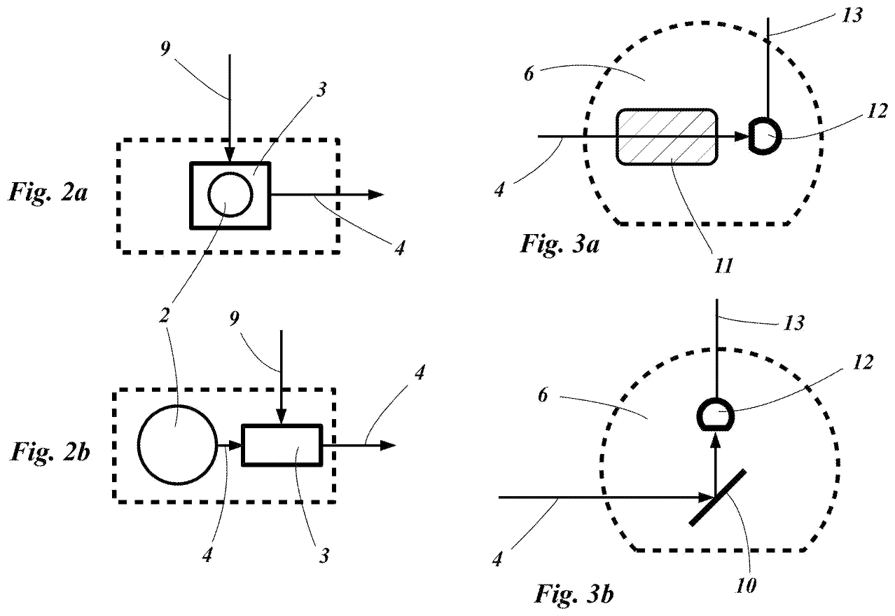

FIG. 2a is a first embodiment example of an arrangement of the source and the resonator with the source in the resonator;

FIG. 2b is a second embodiment example of an arrangement of the source and the resonator with the source outside the resonator;

FIG. 3a is a first embodiment example of the wavelength standard with the gas cell;

FIG. 3b is a second embodiment example of the wavelength standard with the grating;

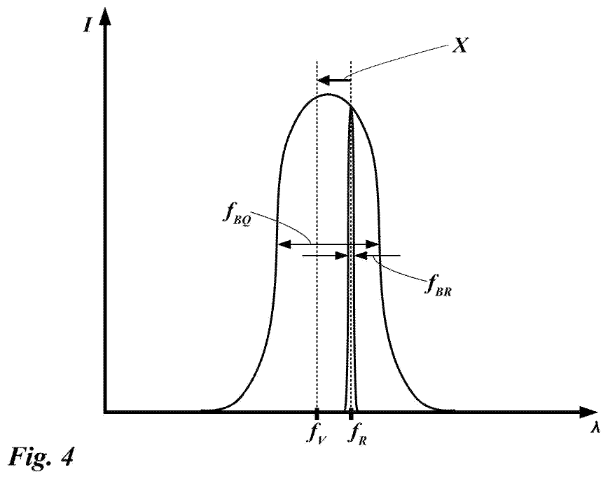

FIG. 4 is a wavelength intensity graph with the source bandwidth f_{BQ}, the resonator bandwidth f RQ and the predetermined wavelength f_{V}; and

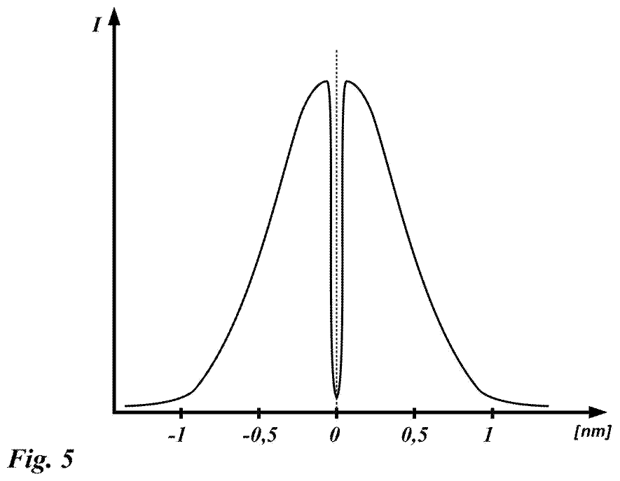

FIG. 5 is a transmission spectrum of a gas in the wavelength standard.

FIG. 1 shows a schematic representation of the method and the device 1 for generating single photons 4 with a predetermined wavelength f_{V}.

In the embodiment example of FIG. 1, a single photon 4 is generated in a source 2 and a resonator 3. The single photon 4 has a resonator wavelength f_{R} and a resonator bandwidth f_{BR} and is then coupled out of the resonator 3 and guided to a wavelength standard 6 via a beam guide 5. The resonator wavelength f_{R} of the single photon 4 is measured in the wavelength standard 6, which generates an electrical signal 13 corresponding to the measured resonator wavelength f_{R}. In the controller 7, the electrical signal 13 is compared with the predetermined wavelength f_{V}. On the basis of the comparison of the resonator wavelength f_{R} and the predetermined wavelength f_{V}, a control signal 9 is generated, which is used to change the resonator 3 toward the predetermined wavelength f_{V} or to the predetermined wavelength f_{V}.

The generation, guiding and measurement of a single photon 4 as well as the generation of the control signal 9 and the adjustment of the resonator wavelength f_{R} is repeated according to the invention until the resonator wavelength f_{R} corresponds to the predetermined wavelength f_{V}.

In the embodiment example of FIG. 1, the source 2 is arranged in the resonator 3. Through the photonic coupling of the resonator 3 to the source 2, the wavelength and the bandwidth of the single photon 4 are adjusted to the resonator wavelength f_{R} and the resonator bandwidth f_{BR}. The photonic coupling reduces the lifespan of the spontaneous emission in the source 2. The source 2 in the embodiment example of FIG. 1 is a two-dimensional hexagonal boron nitride structure with an impurity which is excited by a pulsed laser to generate single photons 4 with the resonator bandwidth f_{BR}. The resonator 3 in the embodiment example of FIG. 1 is formed of two highly reflective resonator walls and a resonator material 14 between the resonator walls. The high reflectance of the resonator walls is generated by a multilayer system with different refractive indices. In the embodiment example of FIG. 1, the distance between the resonator walls can be changed using an electrical signal, for example a piezoelectric signal, as control signal 9, because the control signal 9 acts on the resonator material 14 and thereby brings about a change in length of the resonator material 14 and thus also the change in the distance between the resonator walls.

In the embodiment example of FIG. 1, the resonator wavelength f_{R} of randomly selected single photons 4 is measured in the wavelength standard 6 through the passive beam guide 5. The passive beam guide 5 is formed as a beam splitter in this embodiment example. These measured single photons 4 are used to adjust the resonator 3 and the remaining single photons 4 generated are coupled out toward the output 8. The beam splitter is chosen such that for example on average only every 1000th single photon 4 is guided toward the wavelength standard 6 and the remaining single photons 4 are reflected toward the output 8. In this embodiment example, the regulation of the resonator 3 is always carried out when a single photon 4 is detected on the wavelength standard.

The embodiment example of FIG. 1 can also be formed as an active beam guide 5 in order to carried out the adjustment of the resonator wavelength f_{R} to the predetermined wavelength f_{V} first. After the resonator 3 has been adjusted to the predetermined wavelength f_{V}, the active beam guide 5 can be repositioned in a targeted manner in order to guide the subsequently generated single photons 4 toward the output 8. The active beam guide 5 can be formed for example by a controllable mirror or an electro-optic modulator with a polarization element or an acousto-optic modulator or as a liquid crystal. In such embodiments, the adjustment can be effected in a targeted manner when a control and a regulation of the resonator 3 is carried out.

FIGS. 2a and 2b show different embodiment examples of the arrangement of the source 2 and the resonator 3.

In FIG. 2a, as in the embodiment example of FIG. 1, the source 2 is arranged in the resonator 3, whereby the source 2 is excited only to emit single photons 4 with a resonator wavelength f_{R} and a resonator bandwidth f_{BR} through the arrangement in the resonator 3. The advantage of an arrangement of the source 2 in the resonator 3 is that a spontaneous emission of the single photons 4 in the source 2 with the resonator wavelength f_{R} and with the resonator bandwidth f_{BR} is increased by the resonator 3. In the process, the linewidth of the emission falls to resonator wavelength f_{R} through the coupling of the source 2 to the resonator 3. Further, through the coupling the resonator 3 reduces the lifespan of the excited state and thus increases the emission rate of the single photons 4 with the resonator wavelength f_{R}. In contrast to an arrangement of the source 2 outside the resonator 3, here the single photons 4 are not filtered out of the source bandwidth f_{BQ}, but rather the source 2 is excited directly to emit the single photons 4 with the resonator bandwidth f_{BR}.

In FIG. 2b, the source 2 is arranged in front of the resonator 3. The source 2 has a source bandwidth f_{BQ} predefined by the source 3. In the source, single photons 4 with the source bandwidth f_{BQ} are generated and then coupled into the resonator 3. In the resonator 3, single photons 4 with the resonator bandwidth f_{RQ} are filtered out by the resonator geometry and only these single photons are coupled out of the resonator 3. The advantage of an arrangement of the source 2 outside the resonator 3 is the simple arrangement and formation of the source 2 and the resonator 3.

FIGS. 3a and 3b show different embodiment examples of the wavelength standard 6.

FIG. 3a shows a first embodiment example of the wavelength standard 6 with gas cell 11 and a single-photon detector 12. A single photon 4 is conducted through the gas cell 11 and can be detected behind the gas cell 11 by the single-photon detector 12, which generates an electrical signal 13 in the case of a detection and relays this to the controller 7. The transmission spectrum of the gas cell 11 is represented in FIG. 5. In this embodiment example, the gas in the gas cell 11 absorbs the single photon 4 if the single photon 4 has the predetermined wavelength f_{V}. Thus, when the predetermined wavelength f_{V} is reached, single photons 4 are no longer detected by the single-photon detector 12. The controller 7 is formed as a PI controller in this embodiment example and regulates the resonator 3 such that the electrical signal 13 of the single-photon detector 12 is minimized Since the transmission spectrum of the gas in the gas cell 11 has a minimum both in the case of the predetermined wavelength f_{V} and at the left and right edge, in this embodiment example the transmission spectrum of the gas is measured first in order to determine the starting position of the resonator. This can be effected by actively readjusting the resonator over a broad wavelength range.

FIG. 3b shows a second embodiment example of the wavelength standard 6 with a grating 10. In this embodiment example, corresponding to their resonator wavelength f_{R} single photons 4 are reflected at different angles and reflected toward the single-photon detector 12. In the case of the detection of a single photon 4, the single-photon detector 12 generates the electrical signal 13 and relays it to the controller 7. The predetermined wavelength f_{V} can be adjusted using the position of the single-photon detector 12 and the angle of incidence of the single photon 4. The resolving power of the second embodiment example can be improved through the arrangement of several gratings one behind another.

FIG. 4 shows a schematic representation of the spectrum of the source with the source bandwidth f_{BQ}, the resonator bandwidth f_{BR}, the resonator wavelength f_{R}, the predetermined wavelength f_{V}, to which the resonator 3 is to be adjusted, and the direction of the regulation X. A source 2, arranged outside the resonator 3, has the source bandwidth f_{BQ}. The resonator 3 filters single photons 4 with the resonator bandwidth f_{BR} out of the source bandwidth f_{BQ}. In the case of a source 2 inside the resonator 3, the source 2 has the theoretical source bandwidth f_{BQ}, wherein the source 2 is, however, excited by the resonator 3 only to generate single photons 4 with a resonator bandwidth f_{BR}. The regulation X indicates the direction and the difference in wavelength from the source bandwidth f_{BQ} to the predetermined wavelength f_{V}. It is possible to achieve the adjustment of the resonator 3 through one step or else through several small steps in order to approach the predetermined wavelength f_{V}.

FIG. 5 shows a schematic representation of the transmission spectrum of a gas in a gas cell 11 of an embodiment example of the wavelength standard 6, wherein 0 corresponds to the predetermined wavelength f_{V}.

### LIST OF REFERENCE NUMBERS

1 device for generating single photons with a predetermined wavelength f_{V}
2 source
3 resonator
4 single photon
5 beam guide
6 wavelength standard
7 controller
8 output
9 control signal
10 grating
11 gas cell
12 detector
13 electrical signal
14 resonator material
f_{R} resonator wavelength
f_{BR} resonator bandwidth
f_{Q} source wavelength
f_{BQ} source bandwidth
f_{V} predetermined wavelength
X regulation

1. A method for generating single photons with a predetermined wavelength f_{V} comprising:
i) generating a single photon, wherein the single photon has a resonator wavelength f_{R} and a resonator bandwidth f_{BR};
ii) measuring the resonator wavelength f_{R}, wherein the single photon is guided from a resonator to a wavelength standard via a beam guide;
iii) comparing the resonator wavelength f_{R} with the predetermined wavelength f_{V} and generating a control signal on the basis of the comparison;
iv) adjusting the resonator using the control signal in order to change the resonator wavelength f_{R} toward or to the predetermined wavelength f_{V}; and
v) repeating steps i to iv) until the resonator wavelength f_{R} corresponds to the predetermined wavelength f_{V} and then coupling out a single photon with a predetermined wavelength f_{V} into an output.

2. The method for generating single photons with a predetermined wavelength f_{V} according to claim 1, wherein steps i) to iv) or step v) form a regulation in the case of or during the generation of single photons with the predetermined wavelength f_{V}.

3. The method for generating single photons with a predetermined wavelength f_{V} according to claim 1, wherein at least one of (i) the wavelength of the single photon corresponds to a control variable, (ii) the measured resonator wavelength f_{R} corresponds to an actual value, or (iii) the predetermined wavelength f_{V} corresponds to a set point.

4. The method for generating single photons with a predetermined wavelength f_{V} according to claim 3, wherein in step iii) the controller compares the actual value and the set point and generates the control signal on the basis of the comparison.

5. The method for generating single photons with a predetermined wavelength f_{V} according to claim 1 wherein the method comprises:
a) measuring the resonator wavelength f_{R} in the wavelength standard as measuring device,
b) comparing the resonator wavelength f_{R} with the predetermined wavelength f_{V} and generating the control signal in a controller, and
c) adjusting the resonator using the control signal as actuating means.

6. The method for generating single photons with a predetermined wavelength f_{V} according to claim 1, wherein steps i) to iv) are repeated until the resonator wavelength f_{R} of the single photon generated in step i) lies in a range of ±0.2 nm, around the predetermined wavelength f_{V}.

7. The method for generating single photons with a predetermined wavelength f_{V} according to claim 1, wherein the predetermined wavelength f_{V} is a Fraunhofer line.

8. The method for generating single photons with a predetermined wavelength f_{V} according to claim 1, wherein the single photon is generated in step i) by spontaneous emission or spontaneous parametric conversion.

9. The method for generating single photons with a predetermined wavelength f_{V} according to claim 1, wherein in step i) source is excited by the resonator to emit the single photon with a resonator wavelength f_{R} and a resonator bandwidth f_{BR}, or the source generates a single photon with a source wavelength f_{Q} and a source bandwidth f_{BQ} and the resonator filters therefrom a single photon which has the resonator wavelength f_{R} and the resonator bandwidth f_{BR}, wherein the predetermined wavelength f_{V} and the resonator wavelength f_{R} are contained in the range of the source bandwidth f_{BQ}.

10. The method for generating single photons with a predetermined wavelength f_{V} according to claim 1, wherein in step iv) the resonator is regulated or is formed so that the resonator can be regulated at least one of chemically, thermally, electrically, mechanically or optically.

11. The method for generating single photons with a predetermined wavelength f_{V} according to claim 1, wherein in step i) the resonator is coupled to the source at least one of photonically or mechanically.

12. The method for generating single photons with a predetermined wavelength f_{V} according to claim 1, wherein the measuring in step ii) is effected through a dispersive element or through an absorber.

13. The method for generating single photons with a predetermined wavelength f_{V} according to claim 1, wherein the beam guide is formed switchable in order to guide the single photon from a source and the resonator to a wave standard in step ii) and to guide the single photon from the source and the resonator to the output in step v), or the beam guide is formed as a passive optical element, wherein on average a particular proportion of single photons generated are either guided to the wavelength standard or guided to the output.

14. A device for generating single photons with a predetermined wavelength f_{V} comprising:
a source;
a resonator;
a beam guide; and
a wavelength standard,
wherein the source and the resonator generate single photons with a resonator wavelength f_{R} and a resonator bandwidth f_{BR}, the beam guide guides the single photon from the resonator to the wavelength standard or to an output, and the wavelength standard measures the wavelength of the single photon, and
wherein the device has a controller, and the device has a control circuit for regulating the resonator wavelength f_{R} to the predetermined wavelength f_{V}, and wherein the control circuit is formed of the resonator as actuating means, the wavelength standard as measuring device and the controller for controlling the resonator.

15. The device for generating single photons with a predetermined wavelength f_{V} according to claim 14, wherein the controller is formed as a continuous controller.
